(19) United States
(12) Patent Application Publication
(10) Pub. No.: US 2025/0023588 A1
(43) Pub. Date: Jan. 16, 2025

(54) HIGH FREQUENCY CIRCUIT AND COMMUNICATION DEVICE

(71) Applicant: Murata Manufacturing Co., Ltd., Nagaokakyo-shi (JP)

(72) Inventors: Kenji TAHARA, Nagaokakyo-shi (JP); Kae YAMAMOTO, Nagaokakyo-shi (JP)

(73) Assignee: Murata Manufacturing Co., Ltd., Nagaokakyo-shi (JP)

(21) Appl. No.: 18/900,951

(22) Filed: Sep. 30, 2024

Related U.S. Application Data
(63) Continuation of application No. PCT/JP2023/006221, filed on Feb. 21, 2023.

(30) Foreign Application Priority Data
Apr. 22, 2022 (JP) 2022-071058

(51) Int. Cl. H04B 1/00; H03F 3/24; H04L 5/14

(52) U.S. Cl. CPC H04B 1/0064; H03F 3/245; H04L 5/1461; H03F 2200/165; H03F 2200/171; H03F 2200/451

(57) ABSTRACT

A high frequency circuit includes power amplifiers, filters including a band A in their pass bands, filters including a band B in their pass bands, and a switch circuit that switches the connection between an antenna terminal and two terminals and switches the connection between another antenna terminal and two other terminals. The output end of one power amplifier is connected to the input ends of two of the filters, the output end of one filter is connected to one of the terminals, the output end of another filter is connected to another terminal, the output end of the other power amplifier is connected to the input ends of two others of the filters, the output end of one of the other filters is connected to one of the other terminals, and the output end of another of the other filters is connected to another of the other terminals.

### CROSS-REFERENCE TO RELATED APPLICATIONS

This application is a continuation of international application no. PCT/JP2023/006221, filed Feb. 21, 2023, and which claims priority to Japanese application no. 2022-071058, filed Apr. 22, 2022. The entire contents of both prior applications are hereby incorporated by reference.

### TECHNICAL FIELD

The present disclosure relates to a high frequency circuit and a communication device.

### BACKGROUND ART

A high frequency circuit (power amplifier circuit) includes a first amplifier (carrier amplifier) that amplifies a first signal distributed from an input signal and outputs a second signal in a region where the power level of the input signal is equal to or higher than a first level; a first transformer to which the second signal is inputted; a second amplifier (peak amplifier) that amplifies a third signal distributed from an input signal and outputs a fourth signal in a region where the power level of the input signal is equal to or higher than a second level higher than the first level; and a second transformer to which the fourth signal is inputted.

### SUMMARY

### Technical Problem

When signals of a plurality of bands are to be transmitted simultaneously while ensuring high isolation, the high frequency circuit may become large.

The present disclosure is made to solve the above problem, and it is an exemplary object of the present disclosure to provide a small-sized high frequency circuit and a communication device capable of simultaneously transmitting high frequency signals of a plurality of bands while ensuring high isolation.

### Solution to Problem

A high frequency circuit according to an aspect of the present disclosure is a high frequency circuit capable of simultaneously transmitting a first band and a second band. The high frequency circuit includes a first power amplifier circuit and a second power amplifier circuit. A first multiplexer includes a first filter that includes the first band in its pass band and a second filter that includes the second band in its pass band. A second multiplexer includes a third filter that includes the first band in its pass band and a fourth filter that includes the second band in its pass band. A switch circuit has a first antenna terminal, a second antenna terminal, a first terminal, a second terminal, a third terminal, and a fourth terminal. The switch circuit switches connection between the first antenna terminal and the first terminal and connection between the first antenna terminal and the second terminal. The switch circuit switches connection between the second antenna terminal and the third terminal and connection between the second antenna terminal and the fourth terminal, but does not connect the first antenna terminal to the third terminal and the fourth terminal, and does not connect the second antenna terminal to the first terminal and the second terminal. An output end of the first power amplifier circuit is connected to an input end of the first filter and an input end of the second filter, an output end of the first filter is connected to the first terminal. An output end of the second filter is connected to the second terminal. An output end of the second power amplifier circuit is connected to an input end of the third filter and an input end of the fourth filter, an output end of the third filter is connected to the third terminal, and an output end of the fourth filter is connected to the fourth terminal.

### Exemplary Effects

According to the present disclosure, it is possible to provide a small-sized high frequency circuit and a communication device capable of simultaneously transmitting high frequency signals of a plurality of bands while ensuring high isolation.

### BRIEF DESCRIPTION OF DRAWINGS

FIG. 1 is a circuit configuration diagram of a high frequency circuit and a communication device according to an exemplary embodiment.

FIG. 2 is a circuit configuration diagram of a high frequency circuit and a communication device according to a comparative example.

FIG. 3A is a diagram showing an operation state of a switch circuit according to the exemplary embodiment.

FIG. 3B is a diagram showing an operation state of a switch circuit according to the comparative example.

FIG. 4 is a graph showing the bandpass characteristics of the high frequency circuit according to the exemplary embodiment.

FIG. 5 is a plan view and a cross-sectional view of the high frequency circuit according to the exemplary embodiment.

### DESCRIPTION OF EMBODIMENTS

Exemplary embodiments of the present disclosure will be described in detail below with reference to the drawings. It should be noted that all the exemplary embodiments described below are comprehensive or specific examples. The numerical values, shapes, materials, components, arrangement of components, connection forms and the like shown in the following exemplary embodiments are examples and are not intended to limit the present disclosure. Among the components in the following examples and variations, component(s) not described in the independent claims are described as optional component(s). Also, the size or size ratio of the components shown in the drawings is not necessarily strictly illustrated. In each drawing, substantially identical components are denoted by the same reference signs, and duplicate descriptions may be omitted or simplified.

In the following, description, the terms indicating relationships between elements, such as “parallel” and “orthogonal”, and the terms indicating the shape of elements, such as “rectangular”, as well as numerical ranges do not represent only strict meanings, but also include substantially equivalent ranges, for example, errors of about several percent.

In the following drawings, the x-axis and the y-axis are axes orthogonal to each other on a plane parallel to a main surface of a module substrate. Specifically, when the module substrate has a rectangular shape in plan view, the x-axis is parallel to a first side of the module substrate, and the y-axis is parallel to a second side orthogonal to the first side of the module substrate. The z-axis is an axis perpendicular to the main surface of the module substrate, and the positive direction of the z-axis indicates an upward direction and the negative direction of the z-axis indicates a downward direction.

In circuit configurations of the present disclosure, the term “connected” includes not only when directly connected by connection terminals and/or wiring conductors, but also when electrically connected via other circuit elements. The expression “connected between A and B” means “connected to both A and B, between A and B”, and includes “connected in parallel (shunt) between a path connecting A and B and ground”, in addition to “connected in series with the path”.

In the component arrangement of the present disclosure, the expression “in the plan view of the module substrate” means viewing an object orthographically projected onto the xy plane from the positive side of the z-axis. The expression “A is disposed between B and C” means that at least one of a plurality of line segments connecting an arbitrary point in B and an arbitrary point in C passes through A. The expression “the distance between A and B in the plan view of the module substrate” means the length of a line segment connecting a representative point in the region of A and a representative point in the region of B orthographically projected onto the xy plane. Here, examples of those possible to be used as the representative point include, but are not limited to, the center point of the region, the point closest to the other region, and the like.

In the component arrangement of the present disclosure, the expression “a component is disposed on the substrate” includes that the component is disposed on the main surface of the substrate and that the component is disposed in the substrate. The expression “a component is disposed on the main surface of the substrate” includes that the component is disposed above the main surface without contacting the main surface (for example, a component is stacked on another component disposed in contact with a main surface) in addition to that the component is disposed in contact with the main surface of the substrate. The expression “a component is disposed on the main surface of the substrate” may also include that the component is disposed in a recessed portion formed in the main surface. The expression “a component is disposed in the substrate” includes that the entire component is disposed between both main surfaces of the substrate but a portion of the component is not covered by the substrate and that only a portion of the component is disposed in the substrate, in addition to that the component is encapsulated in the module substrate.

In the present disclosure, the term “signal path” means a transmission line composed of a wire through which a high frequency signal propagates, electrodes directly connected to the wire, terminals directly connected to the wire or the electrodes, and/or the like.

### EMBODIMENTS

### [1. Circuit Configuration of High Frequency Circuit 1 and Communication Device 4]

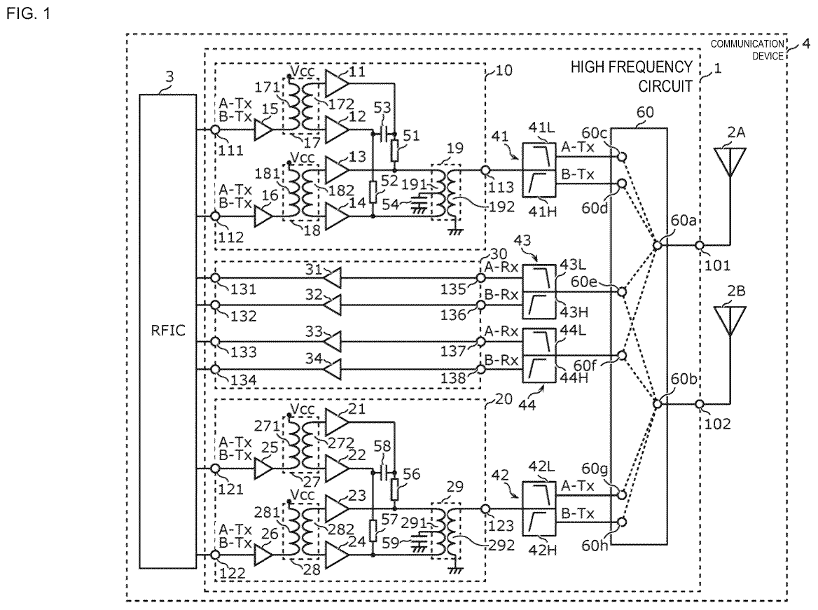

The circuit configuration of a high frequency circuit 1 and a communication device 4 according to an exemplary embodiment will be described with reference to FIG. 1. FIG. 1 is a circuit configuration diagram of the high frequency circuit 1 and the communication device 4 according to the exemplary embodiment.

### [1.1 Circuit Configuration of Communication Device 4]

First, the circuit configuration of the communication device 4 will be described. As shown in FIG. 1, the communication device 4 according to the present exemplary embodiment includes the high frequency circuit 1, antennas 2A and 2B, and an RF signal processing circuit (RFIC) 3.

The high frequency circuit 1 transmits a high frequency signal between the antennas 2A and 2B and the RFIC 3. The detailed circuit configuration of the high frequency circuit 1 will be described later.

The antenna 2A is connected to an antenna connection terminal 101 of the high frequency circuit 1. The antenna 2B is connected to an antenna connection terminal 102 of the high frequency circuit 1. The antennas 2A and 2B transmit a high frequency signal outputted from the high frequency circuit 1, and receive a high frequency signal from the outside and output the received high frequency signal to the high frequency circuit 1.

The RFIC 3 is an example of a signal processing circuit for processing the high frequency signal. Specifically, the RFIC 3 processes a received signal inputted via a reception path of the high frequency circuit 1 by down-converting or the like, and outputs a received signal generated by the signal processing to a baseband signal processing circuit (BBIC, not shown). Further, the RFIC 3 processes the transmission signal input from the BBIC by up-converting or the like, and outputs a transmission signal generated by the signal processing to a transmission path of the high frequency circuit 1. The RFIC 3 has a control unit for controlling switches, amplifying elements, bias circuits, and the like of the high frequency circuit 1. Note that a part or all of the functions as the control unit of the RFIC 3 may alternatively be implemented outside the RFIC 3, for example, in the BBIC or in the high frequency circuit 1.

The RFIC 3 also functions as a control unit for controlling a power supply voltage and a bias voltage supplied to each amplifier of the high frequency circuit 1. Specifically, the RFIC 3 outputs a digital control signal to the high frequency circuit 1. The power supply voltage and the bias voltage controlled by the digital control signal are supplied to each amplifier of the high frequency circuit 1.

Note that the control unit may alternatively be included in the high frequency circuit 1 as an amplifier control circuit. In such a case, the amplifier control circuit outputs a control signal for controlling the power supply voltage and the bias current to a power supply circuit and a bias circuit in accordance with the control signal received from the RFIC 3.

Further, the RFIC 3 determines which high frequency signal of a band A or a band B is to be outputted to signal input terminals 111, 112, 121 and 122 of the high frequency circuit 1 based on the band to be used (the frequency band).

In the communication device 4 according to the present exemplary embodiment, the antennas 2A and 2B are not essential components.

### [1.2 Circuit Configuration of High Frequency Circuit 1]

Next, the circuit configuration of the high frequency circuit 1 will be described. As shown in FIG. 1, the high frequency circuit 1 includes power amplifier circuits 10 and 20, a low-noise amplifier circuit 30, diplexers 41, 42, 43 and 44, a switch circuit 60, and the antenna connection terminals 101 and 102.

The power amplifier circuit 10, which is an example of a first power amplifier circuit, amplifies high frequency transmission signals of the band A and the band B (hereinafter referred to as transmission signals) inputted from the signal input terminals 111 and 112, and outputs the amplified transmission signals from a signal output terminal 113. The power amplifier circuit 20, which is an example of a second power amplifier circuit, amplifies transmission signals of the band A and the band B inputted from the signal input terminals 121 and 122, and outputs the amplified transmission signals from a signal output terminal 123. The low-noise amplifier circuit 30 amplifies high frequency received signals (hereinafter referred to as received signals) of the band A and band B inputted from signal input terminals 135 to 138, and outputs the amplified received signals from signal output terminals 131 to 134.

The band A is an example of a first band, and the band B is an example of a second band; the band A and the band B are frequency bands for a communication system constructed using RAT (Radio Access Technology). The bands A and B are predefined by a standardization organization or the like (for example, 3GPP (registered trademark) (3rd Generation Partnership Project) and IEEE (Institute of Electrical and Electronics Engineers), and the like). Examples of the communication systems include a 5GNR (5th Generation New Radio) system, an LTE (Long Term Evolution) system, and a WLAN (Wireless Local Area Network) system. The band A and the band B are bands that allow simultaneous transmission and/or simultaneous reception. The band A and the band B allow simultaneous transmission as long as they satisfy the combination of the bands that allow simultaneous transmission described in the standards of the standardization organization.

In the high frequency circuit 1 according to the present exemplary embodiment, the band A is, for example, Band B40 for 4G-LTE or Band n40 (2300 to 2400 MHZ) for 5G-NR, and the band B is, for example, Band B41 for 4G-LTE or Band n41 (2496 to 2690 MHZ) for 5G-NR.

Alternatively, the band A may be, for example, Band B77 for 4G-LTE or Band n77 (3300 to 4200 MHZ) for 5G-NR, and the band B may be, for example, Band B79 for 4G-LTE or Band n79 (4400 to 5000 MHz) for 5G-NR.

Detailed circuit configurations of the power amplifier circuits 10 and 20 and the low-noise amplifier circuit 30 will be described later.

The diplexer 41 is an example of a first multiplexer, and includes filters 41L and 41H. The filter 41L is an example of a first filter, and is a low pass filter for transmission that includes the band A in its pass band and the band B in its attenuation band. Note that the filter 41L need not be a low pass filter, but may also be a band pass filter. The filter 41H is an example of a second filter, and is a high pass filter for transmission that includes the band B in its pass band and the band A in its attenuation band. Note that the filter 41H need not be a high pass filter, but may also be a band pass filter.

The input end of the filter 41L and the input end of the filter 41H are connected. Thus, the diplexer 41 outputs, among the transmission signals inputted from the input ends of the filters 41L and 41H, the transmission signal of the band A from the output end of the filter 41L, and outputs, among the transmission signals inputted from the input ends of the filters 41L and 41H, the transmission signal of the band B from the output end of the filter 41H.

The diplexer 42 is an example of a second multiplexer, and includes filters 42L and 42H. The filter 42L is an example of a third filter, and is a low pass filter for transmission that includes the band A in its pass band and the band B in its attenuation band. Note that the filter 42L need not be a low pass filter, but may also be a band pass filter. The filter 42H is an example of a fourth filter, and is a high pass filter for transmission that includes the band B in its pass band and the band A in its attenuation band. Note that the filter 42H need not be a high pass filter, but may also be a band pass filter.

The input end of the filter 42L and the input end of the filter 42H are connected. Thus, the diplexer 42 outputs, among the transmission signals inputted from the input ends of the filters 42L and 42H, the transmission signal of the band A from the output end of the filter 42L, and outputs, among the transmission signals inputted from the input ends of the filters 42L and 42H, the transmission signal of the band B from the output end of the filter 42H.

The diplexer 43 includes filters 43L and 43H. The filter 43L is a low pass filter for reception that includes the band A in its pass band and the band B in its attenuation band. Note that the filter 43L need not be a low pass filter, but may also be a band pass filter. The filter 43H is a high pass filter for reception that includes the band B in its pass band and the band A in its attenuation band. Note that the filter 43H need not be a high pass filter, but may also be a band pass filter.

The input end of the filter 43L and the input end of the filter 43H are connected. Thus, the diplexer 43 outputs, among the received signals inputted from the input ends of the filters 43L and 43H, the received signal of the band A from the output end of the filter 43L, and outputs, among received signals inputted from the input ends of the filters 43L and 43H, the received signal of the band B from the output end of the filter 43H.

The diplexer 44 includes filters 44L and 44H. The filter 44L is a low pass filter for reception that includes the band A in its pass band and the band B in its attenuation band. Note that the filter 44L need not be a low pass filter, but may also be a band pass filter. The filter 44H is a high pass filter for reception that includes the band B in its pass band and the band A in its attenuation band. Note that the filter 44H need not be a high pass filter, but may also be a band pass filter.

The input end of the filter 44L and the input end of the filter 44H are connected. Thus, the diplexer 44 outputs, among the received signals inputted from the input ends of the filters 44L and 44H, the received signal of the band A from the output end of the filter 44L, and outputs, among the received signals inputted from the input ends of the filters 44L and 44H, the received signal of the band B from the output end of the filter 44H.

The switch circuit 60 has an antenna terminal 60a (first antenna terminal), an antenna terminal 60b (second antenna terminal), a terminal 60c (first terminal), a terminal 60d (second terminal), a terminal 60e (fifth terminal), a terminal 60f (fifth terminal), a terminal 60g (third terminal), and a terminal 60h (fourth terminal). The switch circuit 60 switches the connection between the antenna terminal 60a and the terminal 60c and the connection between the antenna terminal 60a and the terminal 60d, and switches the connection between the antenna terminal 60b and the terminal 60g and the connection between the antenna terminal 60b and the terminal 60h. The switch circuit 60 does not connect the antenna terminal 60a to the terminals 60g and 60h, and does not connect the antenna terminal 60b to the terminals 60c and 60d. Further, the switch circuit 60 switches the connection and disconnection between the antenna terminal 60a and each of the terminals 60e and 60f, and switches the connection and disconnection between the antenna terminal 60b and each of the terminals 60e and 60f.

The signal output terminal 113 of the power amplifier circuit 10 is connected to the input end of the filter 41L and the input end of the filter 41H. The output end of the filter 41L is connected to the terminal 60c, and the output end of the filter 41H is connected to the terminal 60d.

Each of the antenna connection terminals 101 and 102, the antenna terminals 60a and 60b, and the terminals 60c, 60d, 60e, 60f, 60g and 60h may be a metal conductor such as a metal electrode and a metal bump, or may be a single point on a metal wire.

The signal output terminal 123 of the power amplifier circuit 20 is connected to the input end of the filter 42L and the input end of the filter 42H. The output end of the filter 42L is connected to the terminal 60g, and the output end of the filter 42H is connected to the terminal 60h.

The signal input terminal 135 of the low-noise amplifier circuit 30 is connected to the output end of the filter 43L, the signal input terminal 136 of the low-noise amplifier circuit 30 is connected to the output end of the filter 43H, the signal input terminal 137 of the low-noise amplifier circuit 30 is connected to the output end of the filter 44L, and the signal input terminal 138 of the low-noise amplifier circuit 30 is connected to the output end of the filter 44H. The input end of the filter 43L and the input end of the filter 43H are connected to the terminal 60e, and the input end of the filter 44L and the input end of the filter 44H are connected to the terminal 60f.

That is, the signal input terminals 135 and 136 of the low-noise amplifier circuit 30 are connected to the terminal 60e via the diplexer 43, and the signal input terminals 137 and 138 of the low-noise amplifier circuit 30 are connected to the terminal 60f via the diplexer 44.

With the above configuration of the high frequency circuit 1, it is possible to simultaneously transmit the transmission signal of the band A and the transmission signal of the band B.

For example, as a first connection state of the switch circuit 60, the antenna terminal 60a and the terminal 60c are connected, and the antenna terminal 60b and the terminal 60h are connected. Thus, the transmission signal of the band A is outputted to the antenna 2A via the power amplifier circuit 10, the filter 41L, the terminal 60c, the antenna terminal 60a, and the antenna connection terminal 101, and at the same time, the transmission signal of the band B is outputted to the antenna 2B via the power amplifier circuit 20, the filter 42H, the terminal 60h, the antenna terminal 60b, and the antenna connection terminal 102.

For example, as a second connection state of the switch circuit 60, the antenna terminal 60a and the terminal 60d are connected, and the antenna terminal 60b and the terminal 60g are connected. Thus, the transmission signal of the band B is outputted to the antenna 2A via the power amplifier circuit 10, the filter 41H, the terminal 60d, the antenna terminal 60a, and the antenna connection terminal 101, and at the same time, the transmission signal of the band A is outputted to the antenna 2B via the power amplifier circuit 20, the filter 42L, the terminal 60g, the antenna terminal 60b, and the antenna connection terminal 102.

With such an arrangement, it is possible to output one of the transmission signals of the band A and the band B from the power amplifier circuit 10 to the antenna 2A via the diplexer 41 and the antenna terminal 60a, and at the same time, to output the other of the transmission signals of the band A and the band B from the power amplifier circuit 20 to the antenna 2B via the diplexer 42 and the antenna terminal 60b. At this time, the power amplifier circuit 10 and the diplexer 41 can be connected only to the antenna terminal 60a of the antenna terminals 60a and 60b, and the power amplifier circuit 20 and the diplexer 42 can be connected only to the antenna terminal 60b of the antenna terminals 60a and 60b. Therefore, isolation of the signal of the band A and the signal of the band B to be transmitted simultaneously in the switch circuit 60 can be ensured. That is, simultaneous transmission of the transmission signal of the band A and the transmission signal of the band B can be realized while ensuring high isolation by using the small-sized high frequency circuit 1 composed of the two power amplifier circuits 10 and 20, the two diplexers 41 and 42, and the single switch circuit 60.

In the high frequency circuit 1 according to the present exemplary embodiment, the low-noise amplifier circuit 30 and the diplexers 43 and 44 may be omitted. In such a case, the terminals 60e and 60f of the switch circuit 60 may be omitted.

Next, the circuit configurations of the power amplifier circuits 10 and 20 and the low-noise amplifier circuit 30 will be described.

The power amplifier circuit 10 is a Doherty type amplifier circuit that amplifies and transmits the transmission signal of the band A and the transmission signal of the band B. As shown in FIG. 1, the power amplifier circuit 10 includes preamplifiers 15 and 16, carrier amplifiers 11 and 12, peak amplifiers 13 and 14, transformers 17, 18 and 19, capacitors 53 and 54, phase shift lines 51 and 52, the signal input terminals 111 and 112, and the signal output terminal 113.

Each of the signal input terminals 111 and 112 and the signal output terminal 113 may be a metal conductor such as a metal electrode and a metal bump, or may be a single point on a metal wire.

The Doherty type amplifier circuit means an amplifier circuit that achieves high efficiency by using a plurality of amplifiers as carrier amplifier(s) and peak amplifier(s). The carrier amplifier means an amplifier that operates in the Doherty type amplifier circuit regardless of whether the (input) power of the high frequency signal is low or high. The peak amplifier means an amplifier that operates mainly when the (input) power of the high frequency signal is high in the Doherty type amplifier circuit. Therefore, when the input power of the high frequency signal is low, the high frequency signal is amplified mainly by the carrier amplifier, and when the input power of the high frequency signal is high, the high frequency signal is amplified and combined by the carrier amplifier and the peak amplifier. Due to such operation, in the Doherty type amplifier circuit, the load impedance at low output power is increased when seen from the carrier amplifier, so that the efficiency at low output power is improved.

In the high frequency circuit according to the present disclosure, when the output signal of the carrier amplifier and the output signal of the peak amplifier are combined in current, the amplifier having a phase shift circuit, which shifts the phase of the high frequency signal by ¼ wavelength, connected to its output end is identified as the carrier amplifier, and the amplifier having no phase shift circuit, which shifts the phase of the high frequency signal by ¼ wavelength, connected to its output end is identified as the peak amplifier.

The preamplifier 15 amplifies the transmission signal of the band A or the band B inputted from the signal input terminal 111. The preamplifier 16 amplifies the transmission signal of the band A or the band B inputted from the signal input terminal 112.

The transformer 17 has a primary coil 171 and a secondary coil 172. One end of the primary coil 171 is connected to a power supply (power supply voltage Vcc), and the other end of the primary coil 171 is connected to the output end of the preamplifier 15. One end of the secondary coil 172 is connected to the input end of the carrier amplifier 11, and the other end of the secondary coil 172 is connected to the input end of the carrier amplifier 12. The transformer 17 converts non-balanced signals output from the preamplifier 15 into balanced signals having an opposite phase relationship to each other.

The transformer 18 has a primary coil 181 and a secondary coil 182. One end of the primary coil 181 is connected to the power supply (power supply voltage Vcc), and the other end of the primary coil 181 is connected to the output end of the preamplifier 16. One end of the secondary coil 182 is connected to the input end of the peak amplifier 13, and the other end of the secondary coil 182 is connected to the input end of the peak amplifier 14. The transformer 18 converts non-balanced signals output from the preamplifier 16 into balanced signals having an opposite phase relationship to each other.

The transformer 19 has a primary coil 191 and a secondary coil 192. One end of the primary coil 191 is connected to the output end of the peak amplifier 13, and the other end of the primary coil 191 is connected to the output end of the peak amplifier 14. One end of the secondary coil 192 is connected to the signal output terminal 113, and the other end of the secondary coil 192 is connected to the ground. The transformer 19 converts a balanced signal obtained by combining the signal output from the carrier amplifier 11 and the signal output from the peak amplifier 13 in current and a balanced signal obtained by combining the signal output from the carrier amplifier 12 and the signal output from the peak amplifier 14 in current into a non-balanced signal.

The carrier amplifiers 11 and 12 are examples of first carrier amplifiers and have amplification transistors. The peak amplifiers 13 and 14 are examples of first peak amplifiers and have amplification transistors. The amplification transistors of the carrier amplifiers and the peak amplifiers are, for example, bipolar transistors such as HBT (Heterojunction Bipolar Transistor) or FET (Field Effect Transistor) such as MOSFET (Metal-Oxide-Semiconductor Field Effect Transistor).

The carrier amplifiers 11 and 12 are class A (or class AB) amplifier circuits capable of performing amplification operations for all power levels of the signal of the band A or band B output from the transformer 17, and can perform highly efficient amplification operations, particularly in a low output region and a medium output region.

The peak amplifiers 13 and 14 are class C amplifier circuits capable of performing an amplification operation in a region where the power level of the signal of the band A or band B output from the transformer 18 is high. Since bias voltages lower than the bias voltages applied to the amplification transistors of the carrier amplifiers 11 and 12 are applied to the amplification transistors of the peak amplifiers 13 and 14, the higher the power level of the signal output from the transformer 18, the lower the output impedance. Thus, the peak amplifiers 13 and 14 can perform low-distortion amplification operations in a high output region.

The output end of the carrier amplifier 11 is connected to one end of the phase shift line 51, and the output end of the carrier amplifier 12 is connected to one end of the phase shift line 52. The other end of the phase shift line 51 is connected to the output end of the peak amplifier 13, and the other end of the phase shift line 52 is connected to the output end of the peak amplifier 14. The phase shift lines 51 and 52 may be phase shift circuits composed of chip-shaped inductors and capacitors.

The capacitor 53 is connected between the output end of the carrier amplifier 11 and the output end of the carrier amplifier 12. The capacitor 54 is connected between the vicinity of the midpoint of the primary coil 191 and the ground. The capacitor 53 has a function of suppressing transmission of harmonic waves output from the carrier amplifiers 11 and 12 to the transformer 19. The capacitor 54 has a function of reducing common mode noise generated by the carrier amplifiers 11 and 12 and the peak amplifiers 13 and 14.

With the above-described connection configuration of the power amplifier circuit 10, the differential signal of the band A or band B outputted from the carrier amplifiers 11 and 12 and the differential signal of the band A or band B outputted from the peak amplifiers 13 and 14 are combined in current, and the signal combined in current is converted into a non-balanced (non-differential) signal by the transformer 19 and outputted from the signal output terminal 113.

Note that the power amplifier circuit 10 does not need to be a differential amplification type amplifier circuit, but needs to have one carrier amplifier, one peak amplifier, and one phase-shifting line. In such a case, the transformers 17 to 19 are unnecessary. The power amplifier circuit 10 does not need to be a Doherty type amplifier circuit, but needs to have at least a power amplifier capable of amplifying the transmission signals of the band A and band B.

The power amplifier circuit 20 is a Doherty type amplifier circuit that amplifies and transmits the transmission signal of the band A and the transmission signal of the band B. As shown in FIG. 1, the power amplifier circuit 20 includes preamplifiers 25 and 26, carrier amplifiers 21 and 22, peak amplifiers 23 and 24, transformers 27, 28 and 29, capacitors 58 and 59, phase shift lines 56 and 57, the signal input terminals 121 and 122, and the signal output terminal 123.

Each of the signal input terminals 121 and 122 and the signal output terminal 123 may be a metal conductor such as a metal electrode and a metal bump, or may be a single point on a metal wire.

The circuit configuration of the power amplifier circuit 20 is the same as the circuit configuration of the power amplifier circuit 10. The preamplifiers 25 and 26, the carrier amplifiers 21 and 22, the peak amplifiers 23 and 24, the transformers 27, 28 and 29, the capacitors 58 and 59, the phase shift lines 56 and 57, the signal input terminals 121 and 122, and the signal output terminal 123 of the power amplifier circuit 20 respectively correspond to the preamplifiers 15 and 16, the carrier amplifiers 11 and 12, the peak amplifiers 13 and 14, the transformers 17, 18 and 19, the capacitors 53 and 54, the phase shift lines 51 and 52, the signal input terminals 111 and 112, and the signal output terminal 113 of the power amplifier circuit 10. Therefore, the description of the detailed circuit configuration of the power amplifier circuit 20 is omitted.

With the configuration of the power amplifier circuit 20, the differential signal of the band A or band B outputted from the carrier amplifiers 21 and 22 and the differential signal of the band A or band B outputted from the peak amplifiers 23 and 24 are combined in current, and the signal combined in current is converted into a non-balanced (non-differential) signal by the transformer 29 and outputted from the signal output terminal 123.

Note that the power amplifier circuit 20 does not need to be a differential amplification type amplifier circuit, but needs to have one carrier amplifier, one peak amplifier, and one phase-shifting line. In such a case, the transformers 27 to 29 are unnecessary. The power amplifier circuit 20 does not need to be a Doherty type amplifier circuit, but needs to have at least a power amplifier capable of amplifying the transmission signals of the band A and band B.

The low-noise amplifier circuit 30 includes low-noise amplifiers 31, 32, 33 and 34, the signal input terminals 135, 136, 137 and 138, and the signal output terminals 131, 132, 133 and 134.

The low-noise amplifier 31 is an example of a first low-noise amplifier, and can amplify the received signal of the band A. The input end of the low-noise amplifier 31 is connected to the output end of the filter 43L via the signal input terminal 135, and the output end of the low-noise amplifier 31 is connected to the RFIC 3 via the signal output terminal 131. The low-noise amplifier 32 is an example of a second low-noise amplifier, and can amplify the received signal of the band B. The input end of the low-noise amplifier 32 is connected to the output end of the filter 43H via the signal input terminal 136, and the output end of the low-noise amplifier 32 is connected to the RFIC 3 via the signal output terminal 132.

The low-noise amplifier 33 is an example of the first low-noise amplifier, and can amplify the received signal of the band A. The input end of the low-noise amplifier 33 is connected to the output end of the filter 44L via the signal input terminal 137, and the output end of the low-noise amplifier 33 is connected to the RFIC 3 via the signal output terminal 133. The low-noise amplifier 34 is an example of the second low-noise amplifier, and can amplify the received signal of the band B. The input end of the low-noise amplifier 34 is connected to the output end of the filter 44H via the signal input terminal 138, and the output end of the low-noise amplifier 34 is connected to the RFIC 3 via the signal output terminal 134.

### [1.3 Circuit Configuration of High Frequency Circuit 500 According to Comparative Example]

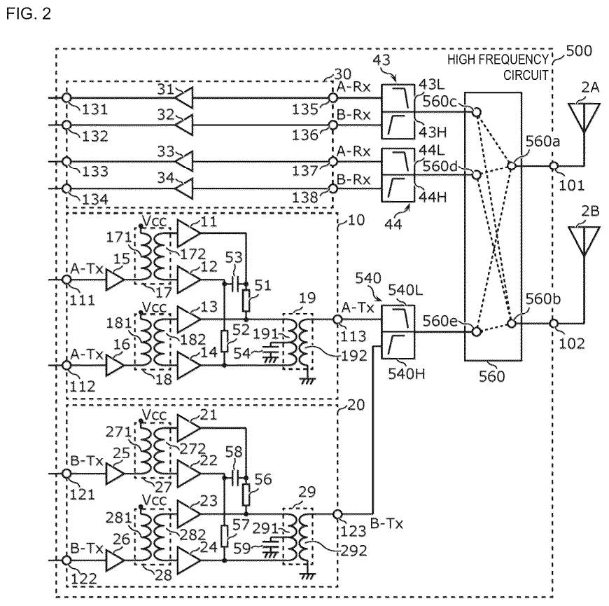

FIG. 2 is a circuit configuration diagram of a high frequency circuit 500 according to a comparative example. As shown in FIG. 2, the high frequency circuit 500 includes power amplifier circuits 10 and 20, a low-noise amplifier circuit 30, diplexers 43, 44 and 540, a switch circuit 560, and antenna connection terminals 101 and 102.

The high frequency circuit 500 according to the comparative example is different from the high frequency circuit 1 according to the exemplary embodiment in that the diplexer 540 is provided instead of the diplexers 41 and 42, and in the configuration of the switch circuit 560. Hereinafter, the high frequency circuit 500 according to the comparative example will be described focusing on the configurations that are different from those of the high frequency circuit 1 according to the exemplary embodiment and omitting descriptions of the same configurations as those of the high frequency circuit 1 according to the exemplary embodiment.

Since the power amplifier circuits 10 and 20 and the low-noise amplifier circuit 30 have the same configuration as those of the high frequency circuit 1 according to the exemplary embodiment, the description thereof will be omitted.

The diplexer 540 includes filters 540L and 540H. The filter 540L is a low pass filter for transmission that includes the band A in its pass band and the band B in its attenuation band. The filter 540H is a high pass filter for transmission that includes the band B in its pass band and the band A in its attenuation band.

The input end of the filter 540L is connected to the signal output terminal 113, and the input end of the filter 540H is connected to the signal output terminal 123. The output end of the filter 540L and the output end of the filter 540H are connected to a terminal 560e of the switch circuit 560. Thus, the diplexer 540 outputs, among the transmission signals input from the power amplifier circuit 10, the transmission signal of the band A to the terminal 560e, and outputs, among the transmission signals input from the power amplifier circuit 20, the transmission signal of the band B to the terminal 560e.

The switch circuit 560 has antenna terminals 560a and 560b, and terminals 560c, 560d and 560e. The switch circuit 560 switches the connection and disconnection between the antenna terminal 560a and any one of the terminals 560c, 560d and 560e, and switches the connection and disconnection between the antenna terminal 560b and any one of the terminals 560c, 560d and 560e.

With the above-described configuration of the high frequency circuit 500 according to the comparative example, it is possible to exclusively output either the transmission signal of the band A or the transmission signal of the band B via the terminal 560e. However, since the transmission signal of the band A and the transmission signal of the band B are output via the single terminal 560e, isolation between the transmission signal of the band A and the transmission signal of the band B cannot be ensured; therefore, it is not possible to simultaneously transmit both the transmission signal of the band A and the transmission signal of the band B.

In contrast, with the high frequency circuit 1 according to the exemplary embodiment, simultaneous transmission of the transmission signal of the band A and the transmission signal of the band B can be realized while ensuring high isolation simply by changing the configuration of the diplexers connected to the power amplifier circuits 10 and 20 with respect to the circuit configuration of the high frequency circuit 500 according to the comparative example.

### [1.4 Isolation Characteristics of High Frequency Circuit]

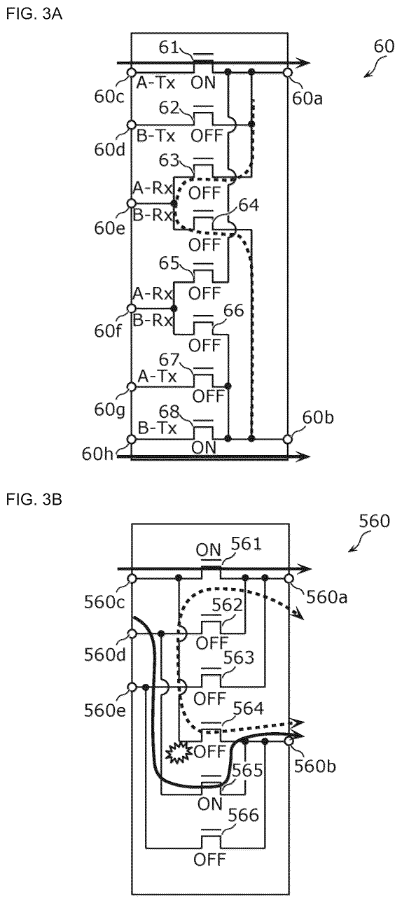

FIG. 3A is a diagram showing an operation state of the switch circuit 60 according to the exemplary embodiment. FIG. 3B is a diagram showing an operation state of the switch circuit 560 according to the comparative example. It is assumed that, in the circuit configuration of the switch circuit 60 shown in FIG. 3A, each of the band A and band B is a TDD (Time Division Duplex) band.

FIGS. 3A and 3B each show an operation state of the switch circuit when the transmission signal of the band A and the transmission signal of the band B are simultaneously transmitted.

If the transmission signal of the band A and the transmission signal of the band B are transmitted simultaneously in the high frequency circuit 500 according to the comparative example, it is assumed that the operation state of the switch circuit 560 is that shown in FIG. 3B. In addition to the antenna terminals 560a and 560b and the terminals 560c, 560d and 560e, the switch circuit 560 further includes switches 561, 562, 563, 564, 565 and 566. One end of the switch 561 is connected to the terminal 560c, and the other end of the switch 561 is connected to the antenna terminal 560a. One end of the switch 562 is connected to the terminal 560d, and the other end of the switch 562 is connected to the antenna terminal 560a. One end of the switch 563 is connected to the terminal 560e, and the other end of the switch 563 is connected to the antenna terminal 560a. One end of the switch 564 is connected to the terminal 560c, and the other end of the switch 564 is connected to the antenna terminal 560b. One end of the switch 565 is connected to the terminal 560d, and the other end of the switch 565 is connected to the antenna terminal 560b. One end of the switch 566 is connected to the terminal 560e, and the other end of the switch 566 is connected to the antenna terminal 560b.

Each of the switches 561 to 566 is, for example, an FET having a gate terminal, a source terminal, and a drain terminal. The gate terminal is not shown in FIG. 3B. Note that each of the switches 561 to 566 may be an FET or a bipolar transistor. When each of the switches 561 to 566 is a bipolar transistor, for example, the source terminal is an emitter terminal, the drain terminal is a collector terminal, and the gate terminal is a base terminal.

In the switch circuit 560, the terminals 560c, 560d and 560e have the same connection configuration with respect to the antenna terminals 560a and 560b. Here, it is assumed that the transmission signal of the band A is transmitted via the terminal 560c, the switch 561, and the antenna terminal 560a (such a transmission path is defined as “transmission path A”), and the transmission signal of the band B is transmitted via the terminal 560d, the switch 566, and the antenna terminal 560b (such a transmission path is defined as “transmission path B”). In such a case, the transmission path A and the transmission path B are connected via the switch 564 in the OFF state. That is, the transmission path A and the transmission path B are coupled by the off-capacitance of the single switch 564, so that an isolation corresponding to the off-capacitance of the single switch 564 is ensured between the transmission signal of the band A and the transmission signal of the band B.

In contrast, when the transmission signal of the band A and the transmission signal of the band B are transmitted simultaneously in the high frequency circuit 1 according to the exemplary embodiment, it is assumed that the operation state of the switch circuit 60 is that shown in FIG. 3A.

In addition to the antenna terminals 60a and 60b and the terminals 60c, 60d, 60e, 60f, 60g and 60h, the switch circuit 60 further includes switches 61, 62, 63, 64, 65, 66, 67 and 68. The switch 61 is an example of a first switch; one end of the switch 61 is connected to the terminal 60c, and the other end of the switch 61 is connected to the antenna terminal 60a. The switch 62 is an example of a second switch; one end of the switch 62 is connected to the terminal 60d, and the other end of the switch 62 is connected to the antenna terminal 60a. The switch 63 is an example of a fifth switch; one end of the switch 63 is connected to the terminal 60e, and the other end of the switch 63 is connected to the antenna terminal 60a. The switch 64 is an example of a sixth switch; one end of the switch 64 is connected to the terminal 60e, and the other end of the switch 64 is connected to the antenna terminal 60b. The switch 65 is an example of the fifth switch; one end of the switch 65 is connected to the terminal 60f, and the other end of the switch 65 is connected to the antenna terminal 60a. The switch 66 is an example of the sixth switch; one end of the switch 66 is connected to the terminal 60f, and the other end of the switch 66 is connected to the antenna terminal 60b. The switch 67 is an example of a third switch; one end of the switch 67 is connected to the terminal 60g, and the other end of the switch 67 is connected to the antenna terminal 60b. The switch 68 is an example of a fourth switch; one end of the switch 68 is connected to the terminal 60h, and the other end of the switch 68 is connected to the antenna terminal 60b.

Each of the switches 61 to 68 is, for example, an FET having a gate terminal, a source terminal, and a drain terminal. The gate terminal is not shown in FIG. 3A. Note that each of the switches 61 to 68 may be an FET or a bipolar transistor. When each of the switches 61 to 68 is a bipolar transistor, for example, the source terminal is an emitter terminal, the drain terminal is a collector terminal, and the gate terminal is a base terminal.

Here, it is assumed that the transmission signal of the band A is transmitted via the terminal 60c, the switch 61, and the antenna terminal 60a (such a transmission path is defined as “transmission path A”), and the transmission signal of the band B is transmitted via the terminal 60h, the switch 68, and the antenna terminal 60b (such a transmission path is defined as “transmission path B”). In such a case, since the received signal of the band A and the received signal of the band B are not transmitted during the period when the transmission signal of the band A and the transmission signal of the band B are transmitted simultaneously, the switches 63 and 64 are in the OFF state. Therefore, the transmission path A and the transmission path B are connected via the switches 63 and 64 in the OFF state. That is, the transmission path A and the transmission path B are coupled by the off-capacitances of the two switches 63 and 64 connected in series, so that an isolation corresponding to the off-capacitance of the two switches 63 and 64 is ensured between the transmission signal of the band A and the transmission signal of the band B.

In the switch circuit 560 according to the comparative example, in order to ensure the same isolation as that of the switch circuit 60 according to the exemplary embodiment, it is necessary to dispose two switches connected in series in the paths connecting the terminals 560c, 560d and 560e and the antenna terminal 560a, and in the paths connecting the terminals 560c, 560d and 560e and the antenna terminal 560b, respectively. However, in such a case, an on-resistance equivalent to that of the two switches connected in series is added to each path during signal transmission, so that transmission loss increases. Further, since two switches are added to each path, the size of the switch circuit 560 increases.

That is, compared to the switch circuit 560 according to the comparative example, the switch circuit 60 according to the exemplary embodiment can largely ensure the isolation due to the off-capacitance of the switch while realizing the miniaturization of the switch circuit 60.

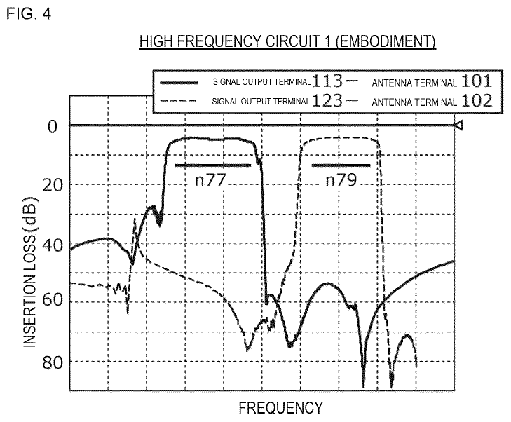

FIG. 4 is a graph showing the bandpass characteristics of the high frequency circuit 1 according to the exemplary embodiment. FIG. 4 shows the bandpass characteristics when the transmission signal of the band A (Band n77 for 5G-NR) and the transmission signal of the band B (Band n79 for 5G-NR) are transmitted simultaneously. As described above, it can be known that, in the high frequency circuit 1 according to the present exemplary embodiment, an isolation of 50 dB or more can be ensured when two transmission signals are transmitted simultaneously due to the arrangement of the diplexers 41 and 42 and the switch circuit 60.

### [2. Mounting Configuration of High Frequency Circuit 1]

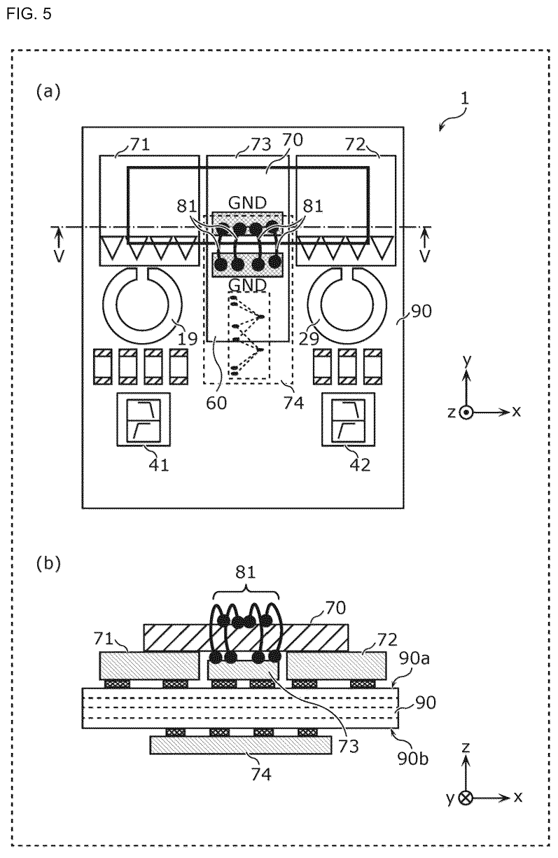

A mounting configuration of the high frequency circuit 1 according to the present exemplary embodiment will be described below with reference to FIG. 5.

FIG. 5 is a plan view and a cross-sectional view of the high frequency circuit 1 according to the present exemplary embodiment. FIG. 5 (a) is a plan view of the high frequency circuit 1, in which the main surface of a module substrate 90 is viewed in a transparent manner from the positive side of the z-axis, and FIG. 5 (b) is a cross-sectional view of the high frequency circuit 1. The cross section of the high frequency circuit 1 in FIG. 5 (b) is taken along line V-V in FIG. 5 (a). In FIG. 5 (a), each amplifier, switch, and diplexer is marked with a mark indicating its function so that the relationship between their arrangement can be easily understood, but the actual amplifiers, switches, and diplexers are not marked with such marks. In FIG. 5, some of the wires connecting the module substrate 90 and each circuit component are omitted.

The high frequency circuit 1 shown in FIG. 5 may further include a resin member covering the main surface of the module substrate 90 and a part of the circuit components, and a shield electrode layer covering the main surface of the resin member; however, the resin member and the shield electrode layer are not shown in FIG. 5.

In addition to the circuit configuration shown in FIG. 1, the high frequency circuit 1 further includes the module substrate 90 and a semiconductor IC 70. Although not shown in FIG. 5, the diplexers 43 and 44 included in the high frequency circuit 1 may be disposed on the module substrate 90.

The module substrate 90 has a main surface 90a (first main surface) and a main surface 90b (second main surface) facing each other, and is a substrate on which the circuit components constituting the high frequency circuit 1 are mounted. For example, a substrate having a multilayer structure formed by stacking a plurality of dielectric layers, a printed circuit board or the like can be used as the module substrate 90, in which examples of the substrate having a multilayer structure formed by stacking a plurality of dielectric layers include an LTCC (Low Temperature Co-fired Ceramics) substrate, an HTCC (High Temperature Co-fired Ceramics) substrate, a substrate with built-in components, and a substrate having an RDL (Redistribution Layer).

Semiconductor ICs 70, 71, 72 and 73, and the diplexers 41 and 42 are disposed on the main surface 90a of the module substrate 90. The semiconductor IC 70 is an example of a third semiconductor IC and includes a control circuit for controlling the power amplifier circuits 10 and 20. The semiconductor IC 71 is an example of a first semiconductor IC and includes at least the carrier amplifiers 11 and 12 and the peak amplifiers 13 and 14 of the power amplifier circuit 10. The semiconductor IC 72 is an example of a second semiconductor IC and includes at least the carrier amplifiers 21 and 22 and the peak amplifiers 23 and 24 of the power amplifier circuit 20. The semiconductor IC 73 is an example of a fourth semiconductor IC and includes at least the low-noise amplifiers 31 to 34.

The transformers 19 and 29 are formed on the main surface 90a of the module substrate 90 or inside the module substrate 90.

A semiconductor IC 74 is disposed on the main surface 90b of the module substrate 90. The semiconductor IC 74 includes the switch circuit 60.

Each of the semiconductor ICs 70 to 74 may be composed by using, for example, CMOS (Complementary Metal Oxide Semiconductor), and more specifically, may be manufactured by an SOI (Silicon on Insulator) process. Each of the semiconductor ICs 70 to 74 may be made of at least one of GaAs, SiGe, and GaN. Note the semiconductor material of the semiconductor ICs 70 to 74 is not limited to the above-described materials.

As shown in FIG. 5, the semiconductor ICs 71 and 72 are disposed on the main surface 90a, and the semiconductor IC 70 is disposed on the semiconductor IC 71 and on the semiconductor IC 72 across the semiconductor ICs 71 and 72.

The semiconductor IC 73 is disposed on the main surface 90a, and is disposed between the semiconductor IC 71 and the semiconductor IC 72 when the main surface 90a is viewed in plan view.

With such an arrangement, since the semiconductor IC 73 is disposed between the semiconductor IC 71 and the semiconductor IC 72, the distance between the power amplifier circuit 10 and the power amplifier circuit 20 can be largely ensured. Therefore, isolation between the transmission signal of the band A and the transmission signal of the band B to be transmitted simultaneously can be ensured. In the case where the band A and band B are TDD bands, since the received signal is not transmitted simultaneously with the transmission signal, the reception sensitivity does not decrease due to the semiconductor IC 73 being disposed between the semiconductor ICs 71 and 72.

Further, as shown in FIG. 5, the high frequency circuit 1 further includes a bonding wire 81 having one end connected to a ground electrode of the semiconductor IC 70 and the other end connected to a ground electrode of the semiconductor IC 73.

With such an arrangement, since the semiconductor IC 73 is disposed between the semiconductor IC 71 and the semiconductor IC 72 and since the bonding wire 81 connected to the ground is disposed, isolation between the transmission signal of the band A and the transmission signal of the band B to be transmitted simultaneously can be ensured at a higher level.

Note that, in the high frequency circuit 1 according to the present exemplary embodiment, the semiconductor IC 73 does not have to be disposed between the semiconductor IC 71 and the semiconductor IC 72. For example, the semiconductor IC 73 may alternatively be disposed on the main surface 90b. In such a case, the bonding wire 81 may have one end connected to the ground electrode of the semiconductor IC 70 and the other end connected to a ground electrode of the module substrate 90 between the semiconductor IC 71 and the semiconductor IC 72.

Even in such a case, since the bonding wire 81 of the ground connection is disposed between the semiconductor IC 71 and the semiconductor IC 72, higher isolation can be ensured between the transmission signal of the band A and the transmission signal of the band B to be transmitted simultaneously.

### [3. Effects and the Like]

As described above, the high frequency circuit 1 according to the present exemplary embodiment is capable of simultaneously transmitting a band A and a band B, and includes: power amplifier circuits 10 and 20; a diplexer 41 including a filter 41L that includes the band A in its pass band and a filter 41H that includes the band B in its pass band; a diplexer 42 including a filter 42L that includes the band A in its pass band and a filter 42H that includes the band B in its pass band; and a switch circuit 60 having antenna terminals 60a and 60b and terminals 60c, 60d, 60g and 60h, switching the connection between the antenna terminal 60a and the terminal 60c and the connection between the antenna terminal 60a and the terminal 60d, switching the connection between the antenna terminal 60b and the terminal 60g and the connection between the antenna terminal 60b and the terminal 60h, not connecting the antenna terminal 60a to the terminals 60g and 60h, and not connecting the antenna terminal 60b to the terminals 60c and 60d. The output end of the power amplifier circuit 10 is connected to the input end of the filter 41L and the input end of the filter 41H, the output end of the filter 41L is connected to the terminal 60c, the output end of the filter 41H is connected to the terminal 60d, the output end of the power amplifier circuit 20 is connected to the input end of the filter 42L and the input end of the filter 42H, the output end of the filter 42L is connected to the terminal 60g, and the output end of the filter 42H is connected to the terminal 60h.

With such an arrangement, it is possible to output the transmission signal of one of the band A and band B from the power amplifier circuit 10 via the diplexer 41 and the antenna terminal 60a, and at the same time, to output the transmission signal of the other of the band A and band B from the power amplifier circuit 20 via the diplexer 42 and the antenna terminal 60b. At this time, the power amplifier circuit 10 and the diplexer 41 can be connected only to the antenna terminal 60a of the antenna terminals 60a and 60b, and the power amplifier circuit 20 and the diplexer 42 can be connected only to the antenna terminal 60b of the antenna terminals 60a and 60b. Therefore, isolation of the signal of the band A and the signal of the band B to be transmitted simultaneously in the switch circuit 60 can be ensured. That is, simultaneous transmission of the transmission signal of the band A and the transmission signal of the band B can be realized while ensuring high isolation by using the small-sized high frequency circuit 1 composed of the two power amplifier circuits 10 and 20, the two diplexers 41 and 42, and the single switch circuit 60.

For example, the high frequency circuit 1 may further include a low-noise amplifier 31 capable of amplifying the high frequency signal of the band A, and the low-noise amplifier 32 capable of amplifying the high frequency signal of the band B, in which the switch circuit 60 may further has a terminal 60e, switch the connection and disconnection between the antenna terminal 60a and the terminal 60e, and switch the connection and disconnection between the antenna terminal 60b and the terminal 60e, and the input end of the low-noise amplifier 31 and the input end of the low-noise amplifier 32 may be connected to the terminal 60e.

With such an arrangement, the received signal of the band A and the received signal of the band B can be transmitted.

For example, in the high frequency circuit 1, each of the band A and band B may be a time division duplex band, and the switch circuit 60 may further have switches 61, 62, 63, 64, 67 and 68, in which: one end of the switch 61 may be connected to the terminal 60c, and the other end of the switch 61 may be connected to the antenna terminal 60a; one end of the switch 62 may be connected to the terminal 60d, and the other end of the switch 62 may be connected to the antenna terminal 60a; one end of the switch 67 may be connected to the terminal 60g, and the other end of the switch 67 may be connected to the antenna terminal 60b; one end of the switch 68 may be connected to the terminal 60h, and the other end of the switch 68 may be connected to the antenna terminal 60b; one end of the switch 63 may be connected to the terminal 60e, and the other end of the switch 63 may be connected to the antenna terminal 60a; one end of the switch 64 may be connected to the terminal 60e, and the other end of the switch 64 may be connected to the antenna terminal 60b.

With such an arrangement, since the transmission signals of the band A and band B only pass through one of the switches 61, 62, 67 and 68 in the switch circuit 60, the on-resistance of the switch when the signals pass can be minimized. Further, when the transmission signal of the band A and the transmission signal of the band B are transmitted simultaneously, the received signal of the band A and the received signal of the band B do not pass, and the switches 63 and 64 are in the OFF state. Therefore, since the switches 63 and 64 in the OFF state are interposed between the transmission path for transmitting the transmission signal of the band A and the transmission path for transmitting the transmission signal of the band B, high isolation between the transmission signal of the band A and the transmission signal of the band B can be ensured.

For example, the high frequency circuit 1 may further include a module substrate 90 that has main surfaces 90a and 90b facing each other, and a control circuit that controls the power amplifier circuits 10 and 20, in which at least a part of the power amplifier circuit 10 may be included in a semiconductor IC 71, at least a part of the power amplifier circuit 20 may be included in a semiconductor IC 72, the control circuit may be included in a semiconductor IC 70, the semiconductor ICs 71 and 72 may be disposed on the main surface 90a, the semiconductor IC 70 may be disposed on the semiconductor IC 71 and on the semiconductor IC 72 across the semiconductor ICs 71 and 72, and the high frequency circuit 1 may further include a bonding wire 81 having one end connected to a ground electrode of the semiconductor IC 70 and the other end connected to a ground electrode of the module substrate 90 between the semiconductor IC 71 and the semiconductor IC 72.

With such an arrangement, since the bonding wire 81 connected to the ground is disposed between the semiconductor IC 71 and the semiconductor IC 72, isolation between the transmission signal of the band A and the transmission signal of the band B can be ensured.

For example, the high frequency circuit 1 may further include a module substrate 90 that has main surfaces 90a and 90b facing each other, and a control circuit that controls the power amplifier circuits 10 and 20, in which at least a part of the power amplifier circuit 10 may be included in a semiconductor IC 71, at least a part of the power amplifier circuit 20 may be included in the semiconductor IC 72, the control circuit may be included in a semiconductor IC 70, the low-noise amplifiers 31 and 32 may be included in a semiconductor IC 73, the semiconductor ICs 71, 72 and 73 may be disposed on the main surface 90a, and the semiconductor IC 73 may be disposed between the semiconductor IC 71 and the semiconductor IC 72 when the main surface 90a is viewed in plan view.

With such an arrangement, since the semiconductor IC 73 is disposed between the semiconductor IC 71 and the semiconductor IC 72, the distance between the power amplifier circuit 10 and the power amplifier circuit 20 can be largely ensured, so that isolation between the transmission signal of the band A and the transmission signal of the band B can be ensured.

For example, in the high frequency circuit 1, the semiconductor IC 70 may be disposed on the semiconductor IC 71 and on the semiconductor IC 72 across the semiconductor ICs 71 and 72, and the high frequency circuit 1 may further include a bonding wire 81 having one end connected to a ground electrode of the semiconductor IC 70 and the other end connected to a ground electrode of the semiconductor IC 73.

With such an arrangement, since the semiconductor IC 73 is disposed between the semiconductor IC 71 and the semiconductor IC 72 and since the bonding wire 81 connected to the ground is disposed, isolation between the transmission signal of the band A and the transmission signal of the band B can be ensured.

For example, in the high frequency circuit 1, the power amplifier circuit 10 may include a carrier amplifier 11 and a peak amplifier 13, in which the output end of the carrier amplifier 11 and the output end of the peak amplifier 13 may be connected to the input end of the filter 41L and the input end of the filter 41H, and the power amplifier circuit 20 may include a carrier amplifier 21 and a peak amplifier 23, wherein and the output end of the carrier amplifier 21 and the output end of the peak amplifier 23 may be connected to the input end of the filter 42L and the input end of the filter 42H.

With such an arrangement, the transmission signal of one of the band A and band B outputted from the carrier amplifier 11 and the transmission signal of the aforesaid one of the band A and band B outputted from the peak amplifier 13 are combined in current, and the signal combined in current is converted into a non-balanced (non-differential) signal by the transformer 19 and outputted from the signal output terminal 113. Further, the transmission signal of the other of the band A and band B outputted from the carrier amplifier 21 and the transmission signal of the aforesaid other of the band A and band B outputted from the peak amplifier 23 are combined in current, and the signal combined in current is converted into a non-balanced (non-differential) signal by the transformer 29 and outputted from the signal output terminal 123.

For example, in the high frequency circuit 1, the band A may be Band B40 for 4G-LTE or Band n40 for 5G-NR, and the band B may be Band B41 for 4G-LTE or Band n41 for 5G-NR.

For example, in the high frequency circuit 1, the band A may be Band B77 for 4G-LTE or Band n77 for 5G-NR, and the band B may be Band B79 for 4G-LTE or Band n79 for 5G-NR.

The communication device 4 according to the present exemplary embodiment includes an RFIC 3 that processes a high frequency signal, and a high frequency circuit 1 that transmits the high frequency signal between the RFIC 3 and antennas 2A and 2B.

With such an arrangement, the effect of the high frequency circuit 1 can be realized in the communication device 4.

### Other Embodiments and the Like

The high frequency circuit and the communication device according to the exemplary embodiment of the present disclosure have been described above; however, the high frequency circuit and the communication device according to the present disclosure are not limited to the exemplary embodiment described above. The present disclosure also includes other exemplary embodiments realized by combining arbitrary components of the above exemplary embodiment, modified examples obtained by applying various modifications that a person skilled in the art can think of to the above exemplary embodiment without departing from the spirit of the present disclosure, and various devices incorporating the above high frequency circuit and the communication device.

In the high frequency circuit and the communication device according to the above exemplary embodiments, for example, other circuit elements and wiring may be inserted between paths connecting the circuit elements and signal paths disclosed in the drawings.

Features of the high frequency circuit and the communication device according to the above exemplary embodiments will be described below.

<1>

A high frequency circuit that simultaneously transmits a first band and a second band, comprising:
a first power amplifier circuit and a second power amplifier circuit;
a first multiplexer including a first filter whose pass band includes the first band and a second filter whose pass band includes the second band;
a second multiplexer including a third filter whose pass band includes the first band and a fourth filter whose pass band includes the second band; and
a switch circuit including a first antenna terminal, a second antenna terminal, a first terminal, a second terminal, a third terminal, and a fourth terminal, configured to switch connection between the first antenna terminal and the first terminal and connection between the first antenna terminal and the second terminal, to switch connection between the second antenna terminal and the third terminal and connection between the second antenna terminal and the fourth terminal, not to connect the first antenna terminal to the third terminal and the fourth terminal, and not to connect the second antenna terminal to the first terminal and the second terminal,
wherein
an output end of the first power amplifier circuit is connected to an input end of the first filter and an input end of the second filter,
an output end of the first filter is connected to the first terminal,
an output end of the second filter is connected to the second terminal,
an output end of the second power amplifier circuit is connected to an input end of the third filter and an input end of the fourth filter,
an output end of the third filter is connected to the third terminal, and
an output end of the fourth filter is connected to the fourth terminal.
   <2>

The high frequency circuit according to <1>, further comprising:
a first low-noise amplifier configured to amplify a high frequency signal of the first band; and
a second low-noise amplifier configured to amplify a high frequency signal of the second band,
wherein
the switch circuit further includes a fifth terminal, switches connection and disconnection between the first antenna terminal and the fifth terminal, and switches connection and disconnection between the second antenna terminal and the fifth terminal, and
an input end of the first low-noise amplifier and an input end of the second low-noise amplifier are connected to the fifth terminal.
   <3>

The high frequency circuit according to <2>, wherein
each of the first band and the second band is a time division duplex band,
the switch circuit further includes a first switch, a second switch, a third switch, a fourth switch, a fifth switch, and a sixth switch,
one end of the first switch is connected to the first terminal, and another end of the first switch is connected to the first antenna terminal,
one end of the second switch is connected to the second terminal, and another end of the second switch is connected to the first antenna terminal,
one end of the third switch is connected to the third terminal, and another end of the third switch is connected to the second antenna terminal,
one end of the fourth switch is connected to the fourth terminal, and another end of the fourth switch is connected to the second antenna terminal,
one end of the fifth switch is connected to the fifth terminal, and another end of the fifth switch is connected to the first antenna terminal, and
one end of the sixth switch is connected to the fifth terminal, and another end of the sixth switch is connected to the second antenna terminal.
   <4>

The high frequency circuit according to any one of <1> to <3>, further comprising:
a substrate that includes a first main surface and a second main surface facing each other; and
a control circuit that controls the first power amplifier circuit and the second power amplifier circuit,
wherein
at least a part of the first power amplifier circuit is included in a first semiconductor integrated circuit (IC),
at least a part of the second power amplifier circuit is included in a second semiconductor IC,
the control circuit is included in a third semiconductor IC,
the first semiconductor IC and the second semiconductor IC are disposed on the first main surface,
the third semiconductor IC is disposed on the first semiconductor IC and on the second semiconductor IC across the first semiconductor IC and the second semiconductor IC, and
the high frequency circuit further comprises a bonding wire having one end connected to a ground electrode of the third semiconductor IC and another end connected to a ground electrode of the substrate between the first semiconductor IC and the second semiconductor IC.
   <5>

The high frequency circuit according to <2> or <3>, further comprising:
a substrate that includes a first main surface and a second main surface facing each other; and
a control circuit that controls the first power amplifier circuit and the second power amplifier circuit,
wherein
at least a part of the first power amplifier circuit is included in a first semiconductor integrated circuit (IC),
at least a part of the second power amplifier circuit is included in a second semiconductor IC,
the control circuit is included in a third semiconductor IC,
the first low-noise amplifier and the second low-noise amplifier are included in a fourth semiconductor IC,
the first semiconductor IC, the second semiconductor IC and the fourth semiconductor IC are disposed on the first main surface, and
the fourth semiconductor IC is disposed between the first semiconductor IC and the second semiconductor IC when the first main surface is viewed in plan view.
   <6>

The high frequency circuit according to <5>, wherein
the third semiconductor IC is disposed on the first semiconductor IC and on the second semiconductor IC across the first semiconductor IC and the second semiconductor IC, and
the high frequency circuit further comprises a bonding wire having one end connected to a ground electrode of the third semiconductor IC and another end connected to a ground electrode of the fourth semiconductor IC.
   <7>

The high frequency circuit according to any one of <1> to <6>, wherein
the first power amplifier circuit includes:
   a first carrier amplifier and a first peak amplifier, an output end of the first carrier amplifier and
an output end of the first peak amplifier being connected to an input end of the first filter and an input end of the second filter, and
the second power amplifier circuit includes:
   a second carrier amplifier and a second peak amplifier, an output end of the second carrier amplifier and an output end of the second peak amplifier being connected to an input end of the third filter and an input end of the fourth filter.
      <8>

The high frequency circuit according to any one of <1> to <7>, wherein
the first band is Band B40 for 4G-LTE or Band n40 for 5G-NR, and
the second band is Band B41 for 4G-LTE or Band n41 for 5G-NR.
   <9>

The high frequency circuit according to any one of <1> to <7>, wherein
the first band is Band B77 for 4G-LTE or Band n77 for 5G-NR, and
the second band is Band B79 for 4G-LTE or Band n79 for 5G-NR.
   <10>

A communication device comprising:
a signal processing circuit that processes a high frequency signal; and
a high frequency circuit according to any one of <1> to <9> that transmits the high frequency signal between the signal processing circuit and an antenna.

### INDUSTRIAL APPLICABILITY

The present disclosure, as a high frequency circuit disposed in a multi-band adaptive front-end section, can be widely used in communication devices such as cellular phones.

### REFERENCE SIGNS LIST

1, 500 high frequency circuit
2A, 2B antenna
3 RF signal processing circuit (RFIC)
4 communication device
10, 20 power amplifier circuit
11, 12, 21, 22 carrier amplifier
13, 14, 23, 24 peak amplifier
15, 16, 25, 26 preamplifier
17, 18, 19, 27, 28, 29 transformer
30 low-noise amplifier circuit
31, 32, 33, 34 low-noise amplifier
41, 42, 43, 44, 540 diplexer
41H, 41L, 42H, 42L, 43H, 43L, 44H, 44L, 540H, 540L filter
51, 52, 56, 57 phase shift line
53, 54, 58, 59 capacitor
60, 560 switch circuit
60a, 60b, 560a, 560b antenna terminal
60c, 60d, 60e, 60f, 60g, 60h, 560c, 560d, 560e terminal
61, 62, 63, 64, 65, 66, 67, 68, 561, 562, 563, 564,
565, 566 switch
70, 71, 72, 73, 74 semiconductor IC
81 bonding wire
90 module substrate
90a, 90b main surface
101, 102 antenna connection terminal
111, 112, 121, 122, 135, 136, 137, 138 signal input terminal
113, 123, 131, 132, 133, 134 signal output terminal
171, 181, 191, 271, 281, 291 primary coil
172, 182, 192, 272, 282, 292 secondary coil

1. A high frequency circuit that simultaneously transmits a first band and a second band, comprising:
a first power amplifier circuit and a second power amplifier circuit;
a first multiplexer including a first filter whose pass band includes the first band and a second filter whose pass band includes the second band;
a second multiplexer including a third filter whose pass band includes the first band and a fourth filter whose pass band includes the second band; and
a switch circuit including a first antenna terminal, a second antenna terminal, a first terminal, a second terminal, a third terminal, and a fourth terminal, configured to switch connection between the first antenna terminal and the first terminal and connection between the first antenna terminal and the second terminal, to switch connection between the second antenna terminal and the third terminal and connection between the second antenna terminal and the fourth terminal, not to connect the first antenna terminal to the third terminal and the fourth terminal, and not to connect the second antenna terminal to the first terminal and the second terminal,
wherein
an output end of the first power amplifier circuit is connected to an input end of the first filter and an input end of the second filter,
an output end of the first filter is connected to the first terminal,
an output end of the second filter is connected to the second terminal,
an output end of the second power amplifier circuit is connected to an input end of the third filter and an input end of the fourth filter,
an output end of the third filter is connected to the third terminal, and
an output end of the fourth filter is connected to the fourth terminal.

2. The high frequency circuit according to claim 1, further comprising:
a first low-noise amplifier configured to amplify a high frequency signal of the first band; and
a second low-noise amplifier configured to amplify a high frequency signal of the second band,
wherein
the switch circuit further includes a fifth terminal, that switches connection and disconnection between the first antenna terminal and the fifth terminal, and that switches connection and disconnection between the second antenna terminal and the fifth terminal, and
an input end of the first low-noise amplifier and an input end of the second low-noise amplifier are connected to the fifth terminal.

3. The high frequency circuit according to claim 2, wherein
each of the first band and the second band is a time division duplex band,
the switch circuit further includes a first switch, a second switch, a third switch, a fourth switch, a fifth switch, and a sixth switch,
one end of the first switch is connected to the first terminal, and another end of the first switch is connected to the first antenna terminal,
one end of the second switch is connected to the second terminal, and another end of the second switch is connected to the first antenna terminal,
one end of the third switch is connected to the third terminal, and another end of the third switch is connected to the second antenna terminal,
one end of the fourth switch is connected to the fourth terminal, and another end of the fourth switch is connected to the second antenna terminal,
one end of the fifth switch is connected to the fifth terminal, and another end of the fifth switch is connected to the first antenna terminal, and
one end of the sixth switch is connected to the fifth terminal, and another end of the sixth switch is connected to the second antenna terminal.

4. The high frequency circuit according to claim 1, further comprising:
a substrate that includes a first main surface and a second main surface facing each other; and
a control circuit that controls the first power amplifier circuit and the second power amplifier circuit,
wherein
at least a part of the first power amplifier circuit is included in a first semiconductor integrated circuit (IC),
at least a part of the second power amplifier circuit is included in a second semiconductor IC,
the control circuit is included in a third semiconductor IC,
the first semiconductor IC and the second semiconductor IC are disposed on the first main surface,
the third semiconductor IC is disposed on the first semiconductor IC and on the second semiconductor IC across the first semiconductor IC and the second semiconductor IC, and
the high frequency circuit further comprises a bonding wire having one end connected to a ground electrode of the third semiconductor IC and another end connected to a ground electrode of the substrate between the first semiconductor IC and the second semiconductor IC.

5. The high frequency circuit according to claim 2, further comprising:
a substrate that includes a first main surface and a second main surface facing each other; and
a control circuit that controls the first power amplifier circuit and the second power amplifier circuit,
wherein
at least a part of the first power amplifier circuit is included in a first semiconductor integrated circuit (IC),
at least a part of the second power amplifier circuit is included in a second semiconductor IC,
the control circuit is included in a third semiconductor IC,
the first low-noise amplifier and the second low-noise amplifier are included in a fourth semiconductor IC,
the first semiconductor IC, the second semiconductor IC and the fourth semiconductor IC are disposed on the first main surface, and
the fourth semiconductor IC is disposed between the first semiconductor IC and the second semiconductor IC when the first main surface is viewed in plan view.

6. The high frequency circuit according to claim 5, wherein
the third semiconductor IC is disposed on the first semiconductor IC and on the second semiconductor IC across the first semiconductor IC and the second semiconductor IC, and
the high frequency circuit further comprises a bonding wire having one end connected to a ground electrode of the third semiconductor IC and another end connected to a ground electrode of the fourth semiconductor IC.

7. The high frequency circuit according to claim 1, wherein
the first power amplifier circuit includes:
a first carrier amplifier and a first peak amplifier, an output end of the first carrier amplifier and
an output end of the first peak amplifier being connected to an input end of the first filter and an input end of the second filter, and
the second power amplifier circuit includes:
a second carrier amplifier and a second peak amplifier, an output end of the second carrier amplifier and
an output end of the second peak amplifier being connected to an input end of the third filter and an input end of the fourth filter.

8. The high frequency circuit according to claim 1, wherein
the first band is Band B40 for 4G-LTE or Band n40 for 5G-NR, and
the second band is Band B41 for 4G-LTE or Band n41 for 5G-NR.

9. The high frequency circuit according to claim 1, wherein
the first band is Band B77 for 4G-LTE or Band n77 for 5G-NR, and
the second band is Band B79 for 4G-LTE or Band n79 for 5G-NR.

10. A communication device comprising:
a signal processing circuit that processes a high frequency signal; and
a high frequency circuit according to claim 1 that transmits the high frequency signal between the signal processing circuit and an antenna.

11. The high frequency circuit according to claim 2, further comprising:
a substrate that includes a first main surface and a second main surface facing each other; and
a control circuit that controls the first power amplifier circuit and the second power amplifier circuit,
wherein
at least a part of the first power amplifier circuit is included in a first semiconductor integrated circuit (IC),
at least a part of the second power amplifier circuit is included in a second semiconductor IC,
the control circuit is included in a third semiconductor IC,
the first semiconductor IC and the second semiconductor IC are disposed on the first main surface,
the third semiconductor IC is disposed on the first semiconductor IC and on the second semiconductor IC across the first semiconductor IC and the second semiconductor IC, and
the high frequency circuit further comprises a bonding wire having one end connected to a ground electrode of the third semiconductor IC and another end connected to a ground electrode of the substrate between the first semiconductor IC and the second semiconductor IC.

12. The high frequency circuit according to claim 3, further comprising:
a substrate that includes a first main surface and a second main surface facing each other; and
a control circuit that controls the first power amplifier circuit and the second power amplifier circuit,
wherein
at least a part of the first power amplifier circuit is included in a first semiconductor integrated circuit (IC),
at least a part of the second power amplifier circuit is included in a second semiconductor IC,
the control circuit is included in a third semiconductor IC,
the first semiconductor IC and the second semiconductor IC are disposed on the first main surface,
the third semiconductor IC is disposed on the first semiconductor IC and on the second semiconductor IC across the first semiconductor IC and the second semiconductor IC, and
the high frequency circuit further comprises a bonding wire having one end connected to a ground electrode of the third semiconductor IC and another end connected to a ground electrode of the substrate between the first semiconductor IC and the second semiconductor IC.

13. The high frequency circuit according to claim 3, further comprising:
a substrate that includes a first main surface and a second main surface facing each other; and
a control circuit that controls the first power amplifier circuit and the second power amplifier circuit,
wherein
at least a part of the first power amplifier circuit is included in a first semiconductor integrated circuit (IC),
at least a part of the second power amplifier circuit is included in a second semiconductor IC,
the control circuit is included in a third semiconductor IC,
the first low-noise amplifier and the second low-noise amplifier are included in a fourth semiconductor IC,
the first semiconductor IC, the second semiconductor IC and the fourth semiconductor IC are disposed on the first main surface, and
the fourth semiconductor IC is disposed between the first semiconductor IC and the second semiconductor IC when the first main surface is viewed in plan view.

14. The high frequency circuit according to claim 2, wherein
the first power amplifier circuit includes:
a first carrier amplifier and a first peak amplifier, an output end of the first carrier amplifier and
an output end of the first peak amplifier being connected to an input end of the first filter and an input end of the second filter, and
the second power amplifier circuit includes:
a second carrier amplifier and a second peak amplifier, an output end of the second carrier amplifier and
an output end of the second peak amplifier being connected to an input end of the third filter and an input end of the fourth filter.

15. The high frequency circuit according to claim 3, wherein
the first power amplifier circuit includes:
a first carrier amplifier and a first peak amplifier, an output end of the first carrier amplifier and
an output end of the first peak amplifier being connected to an input end of the first filter and an input end of the second filter, and
the second power amplifier circuit includes:
a second carrier amplifier and a second peak amplifier, an output end of the second carrier amplifier and
an output end of the second peak amplifier being connected to an input end of the third filter and an input end of the fourth filter.

16. The high frequency circuit according to claim 4, wherein
the first power amplifier circuit includes:
a first carrier amplifier and a first peak amplifier, an output end of the first carrier amplifier and
an output end of the first peak amplifier being connected to an input end of the first filter and an input end of the second filter, and
the second power amplifier circuit includes:
a second carrier amplifier and a second peak amplifier, an output end of the second carrier amplifier and
an output end of the second peak amplifier being connected to an input end of the third filter and an input end of the fourth filter.

17. The high frequency circuit according to claim 5, wherein
the first power amplifier circuit includes:
a first carrier amplifier and a first peak amplifier, an output end of the first carrier amplifier and
an output end of the first peak amplifier being connected to an input end of the first filter and an input end of the second filter, and
the second power amplifier circuit includes:
a second carrier amplifier and a second peak amplifier, an output end of the second carrier amplifier and
an output end of the second peak amplifier being connected to an input end of the third filter and an input end of the fourth filter.

18. The high frequency circuit according to claim 6, wherein
the first power amplifier circuit includes:
a first carrier amplifier and a first peak amplifier, an output end of the first carrier amplifier and
an output end of the first peak amplifier being connected to an input end of the first filter and an input end of the second filter, and
the second power amplifier circuit includes:
a second carrier amplifier and a second peak amplifier, an output end of the second carrier amplifier and
an output end of the second peak amplifier being connected to an input end of the third filter and an input end of the fourth filter.

19. The communication device according to claim 10, wherein
the first band is Band B40 for 4G-LTE or Band n40 for 5G-NR, and
the second band is Band B41 for 4G-LTE or Band n41 for 5G-NR.

20. The high frequency circuit according to claim 10, wherein
the first band is Band B77 for 4G-LTE or Band n77 for 5G-NR, and
the second band is Band B79 for 4G-LTE or Band n79 for 5G-NR.
